(19) United States
(12) Patent Application Publication
(10) Pub. No.: US 2026/0215335 A1
(43) Pub. Date: Jul. 23, 2026

(54) PACKAGE AND FABRICATION METHOD THEREOF

(71) Applicant: Taiwan Semiconductor Manufacturing Company, Ltd., Hsinchu (TW)

(72) Inventors: Shu-Huai Hsu, Keelung City (TW); Tzu-Shiun Sheu, Hsinchu (TW); Shih-Hui Wang, New Taipei City (TW); Yung-Ping Chiang, Hsinchu County (TW)

(73) Assignee: Taiwan Semiconductor Manufacturing Company, Ltd., Hsinchu (TW)

(21) Appl. No.: 19/034,390

(22) Filed: Jan. 22, 2025

(51) Int. Cl. H01L 25/18; H01L 21/304; H01L 21/78; H01L 23/00; H01L 23/31; H01L 23/367; H01L 23/42

(52) U.S. Cl. CPC H10W 90/00; H10P 52/00; H10P 54/00; H10W 40/22; H10W 40/70; H10W 74/127; H10W 72/073; H10W 80/312; H10W 80/327; H10W 90/732; H10W 90/734; H10W 90/792; H10W 90/794

(57) ABSTRACT

A package includes a package substrate, a package component, a first auxiliary structure, and an underfill layer. The package component is bonded to the package substrate. The package component has a groove at a bottom side facing the package substrate. The first auxiliary structure is bonded to the package substrate and overlapping with the groove. The underfill layer is vertically disposed between the package component and the package substrate and between the package component and the first auxiliary structure.

### BACKGROUND

With the rapid advancement of semiconductor technology, electronic devices are becoming increasingly thinner and more compact. Typically, these devices incorporate multiple chips, each serving distinct functionalities. To further minimize the overall size of electronic devices, multi-chip packaging techniques are widely adopted, enabling the integration of several chips within a single package. This approach not only effectively shortens the signal transmission paths between chips but also enhances the operational efficiency and performance of the device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1M are schematical cross-sectional views illustrating various stages of a method for manufacturing a package component according to some embodiments of the present disclosure.

FIGS. 2A to 2F are schematical perspective top views illustrating various stages of a method for manufacturing a package component according to some embodiments of the present disclosure.

FIGS. 3A to 3C are schematical top views illustrating various stages of a method for bonding a package component to a package substrate according to some embodiments of the present disclosure.

FIGS. 4A to 4C are schematical cross-sectional views illustrating various stages of a method for bonding a package component to a package substrate according to some embodiments of the present disclosure.

FIG. 5 is a schematical cross-sectional view illustrating a package according to some embodiments of the present disclosure.

FIG. 6 is a schematical cross-sectional view illustrating a package according to some embodiments of the present disclosure.

FIG. 7 is a schematical cross-sectional view illustrating a package according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In semiconductor device fabrication, bonding processes are employed to join different structures. For example, techniques such as hybrid bonding, micro-bumps, metal pillars, electroless nickel-electroless palladium-immersion gold (ENEPIG) bumps, controlled collapse chip connection (C4) bumps, or ball grid array (BGA) bumps may be used to bond one die to another die, a wafer, or other structures. The joints in the bonding process not only secure the die in place but also serve as channels for signal transmission. However, in a package containing various dies, bonding failures are more likely to occur near the edges of the package, especially at the corners, due to warpage or mismatches in the coefficient of thermal expansion (CTE) between the dies and the encapsulation layer. Such bonding failures, including cracks at the bonding interface, may propagate along the bonding interface, leading to delamination issues.

In some embodiments of the present disclosure, portions of the bonding interface between the die (e.g., referred to as the top die) and the structure bonded to the die near the corners of the package component are removed. In other words, the corner portions prone to bonding failures and crack formation are eliminated. This approach prevents the occurrence of cracks and, consequently, avoids delamination issues caused by crack propagation.

In some embodiments, the package component containing multiple dies is bonded to a package substrate, with an underfill layer formed between the package component and the package substrate to protect the connections between them. However, since the underfill layer typically has a higher coefficient of thermal expansion (CTE) compared to semiconductor materials (e.g., silicon), the expansion and contraction of the underfill layer may lead to cracks within the structure. To mitigate this issue, an auxiliary structure is provided on the package substrate at the locations corresponding to the corner portions of the package component.

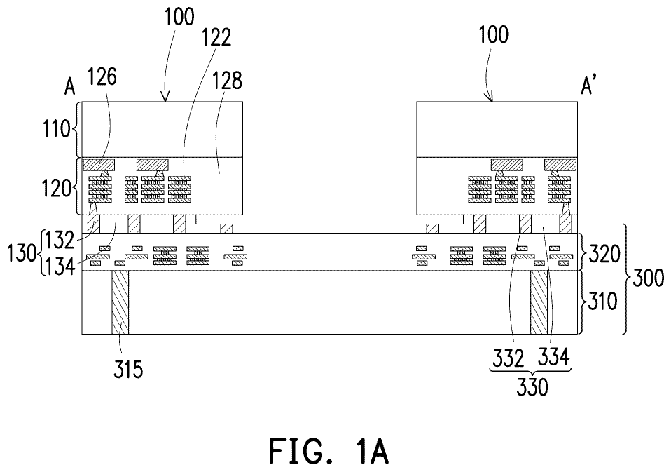

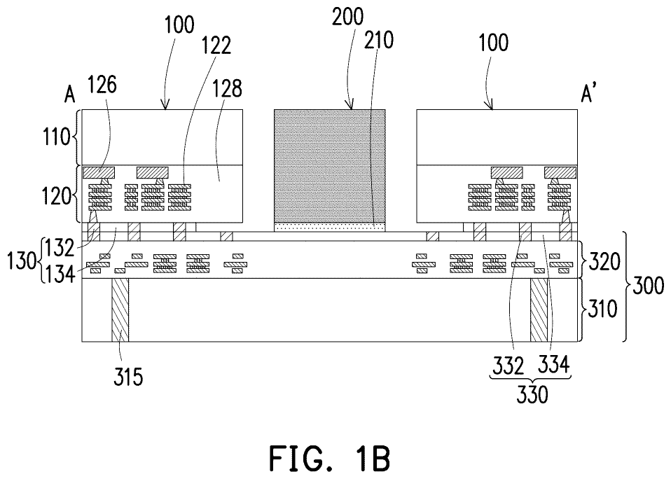

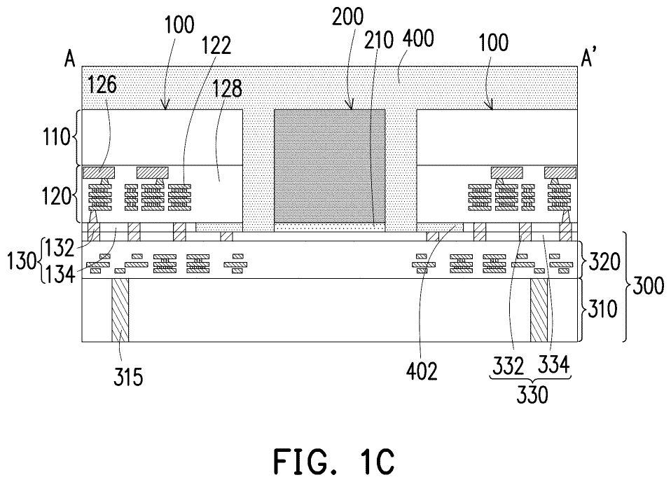

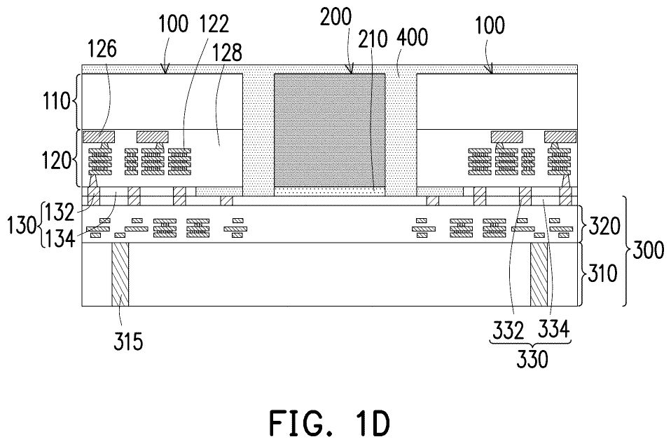

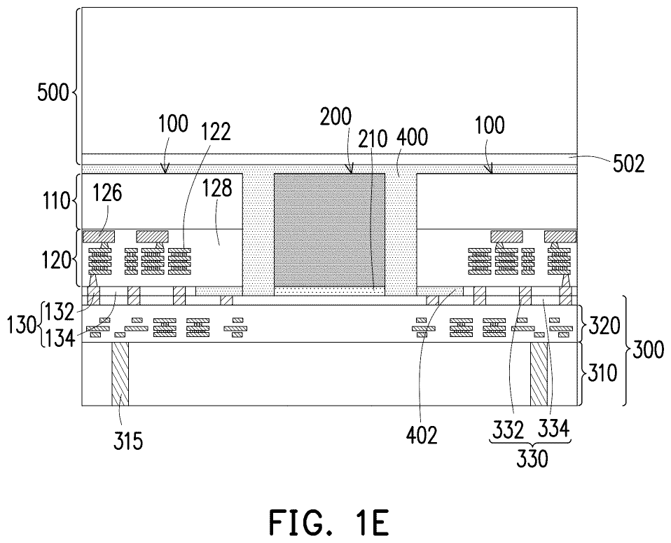

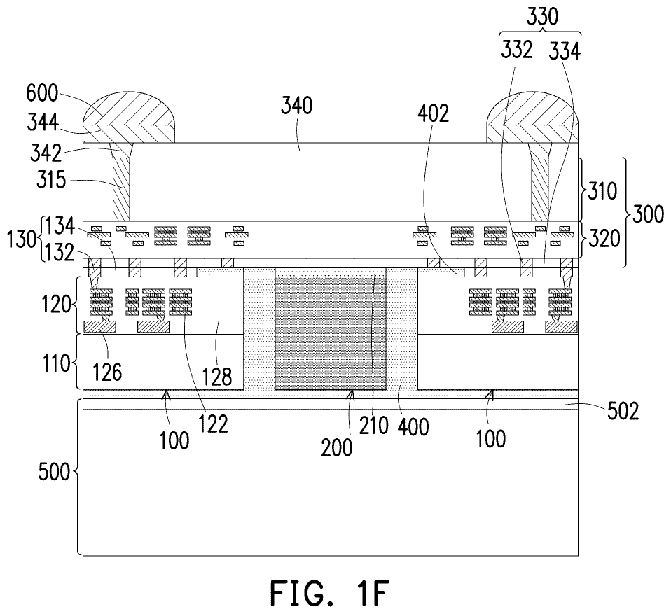

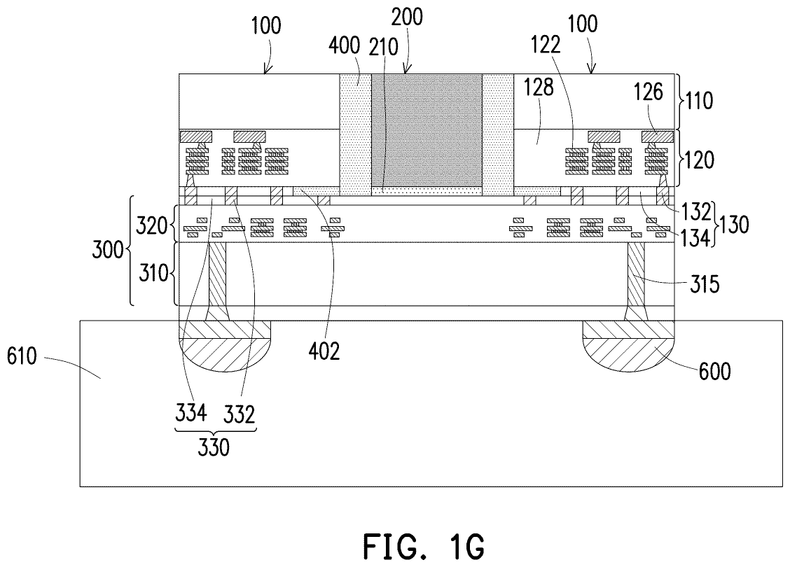

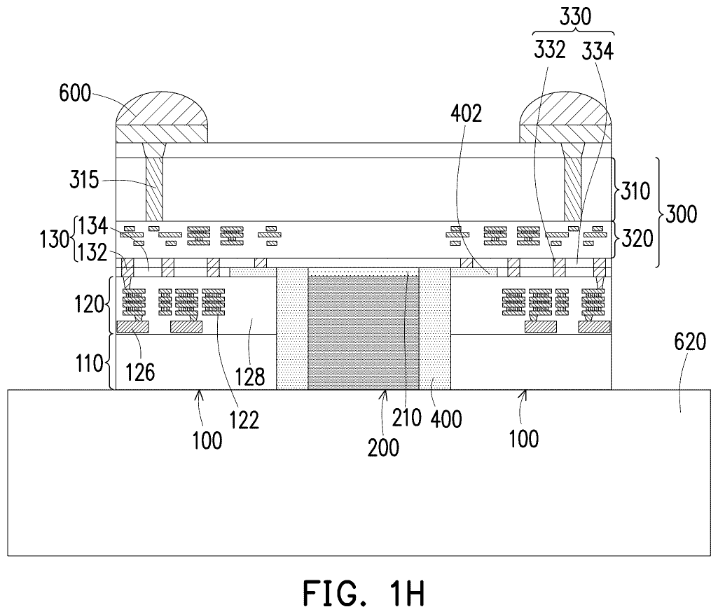

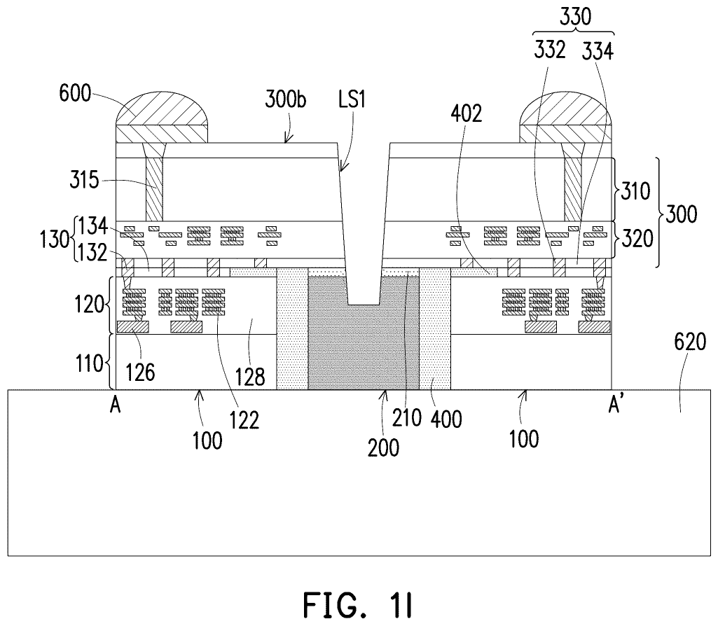

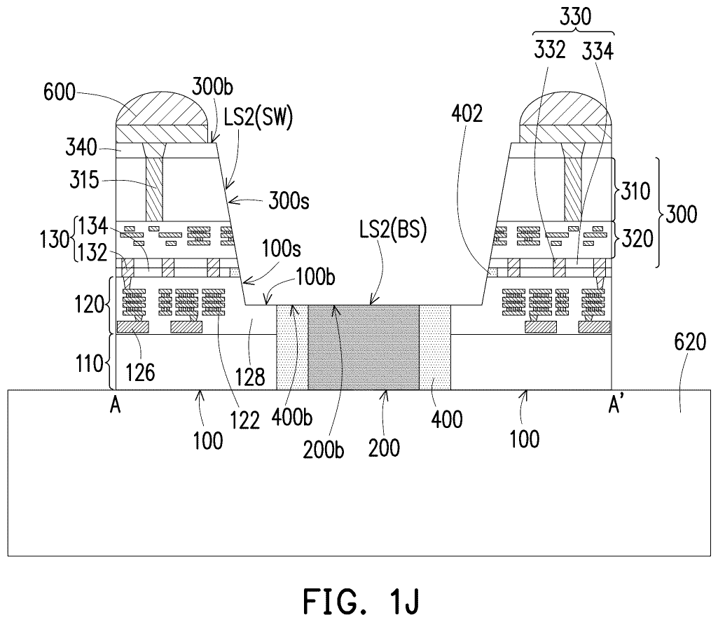

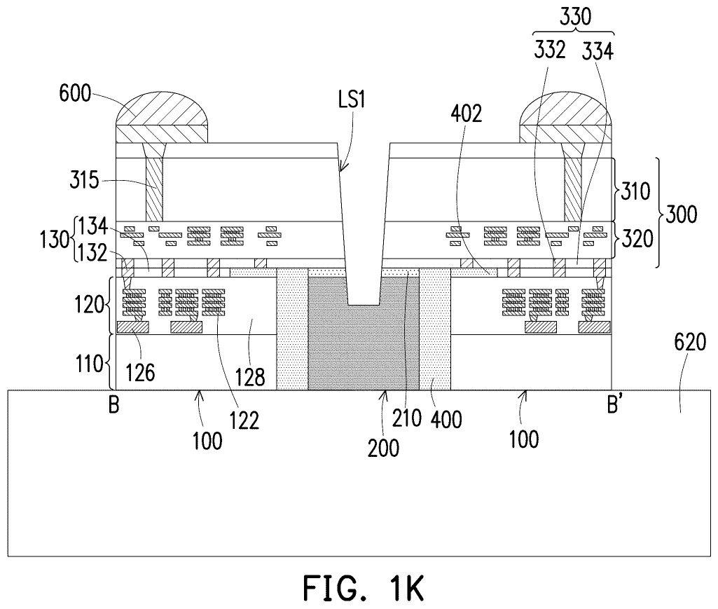

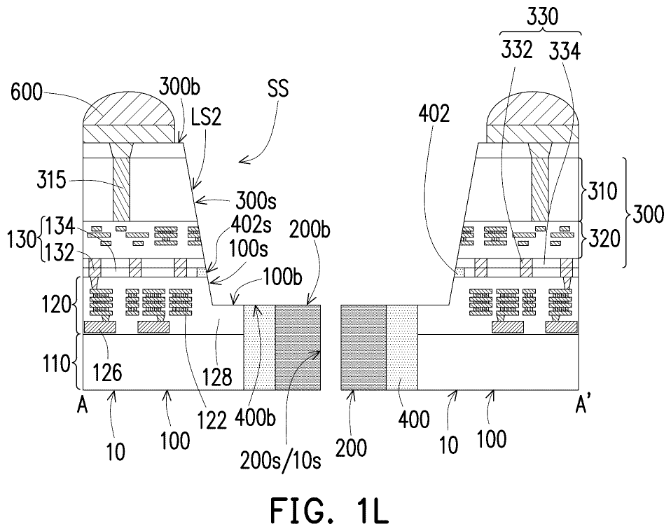

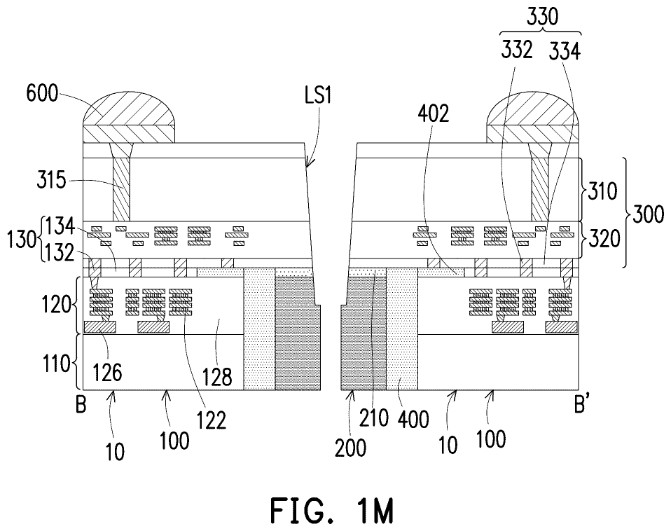

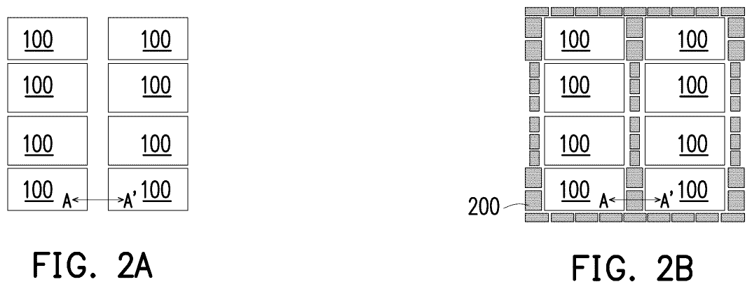

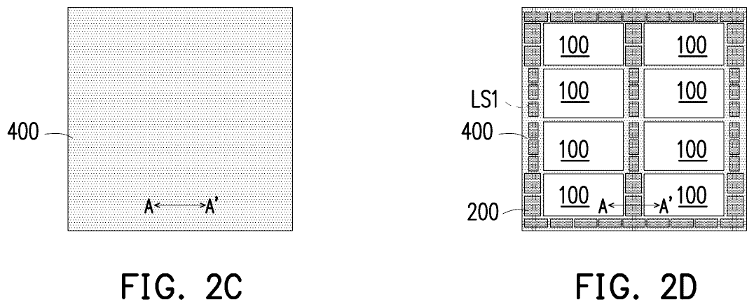

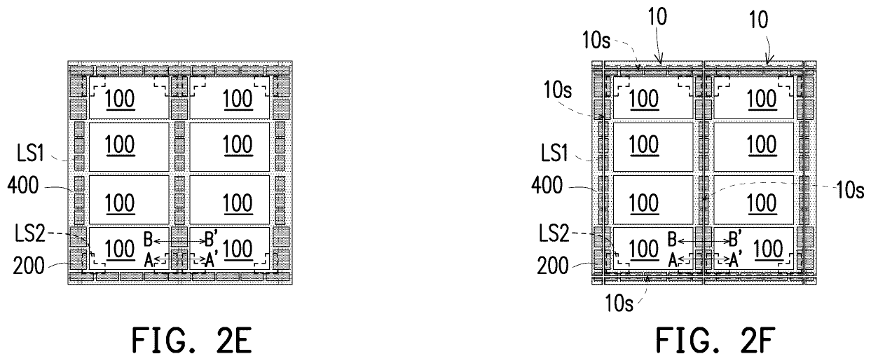

FIGS. 1A to 1M are schematic cross-sectional views illustrating various stages of a method for manufacturing a package component 10 according to some embodiments of the present disclosure. FIGS. 2A to 2F are schematic perspective top views corresponding to the structures shown in FIGS. 1A, 1B, 1C, 1I, 1J, and 1L, respectively. In particular, FIGS. 1A, 1B, 1C, 1I, 1J, and 1L correspond to the cross-sectional views taken along line A-A′ in FIGS. 2A to 2F. Referring to FIGS. 1A and 2A, multiple first dies 100 are provided. In some embodiments, the first dies 100 may also be referred to as top dies. The first dies 100 may include logic dies (e.g., central processing unit (CPU), graphics processing unit (GPU), system-on-a-chip (SoC), microcontroller, etc.), memory dies (e.g., dynamic random access memory (DRAM), static random access memory (SRAM), etc.), power management dies (e.g., power management integrated circuit (PMIC)), radio frequency (RF) dies, sensor dies, micro-electro-mechanical system (MEMS) dies, signal processing dies (e.g., digital signal processing (DSP) dies), front-end dies (e.g., analog front-end (AFE) dies), or any combination thereof.

In some embodiments, the first dies 100 may vary in size (e.g., differing in height and/or surface area), while in other embodiments, the first dies 100 may have uniform size (e.g., the same height and/or surface area).

The first dies 100 each include a semiconductor substrate 110 and an interconnection structure 120. The semiconductor substrate 110 may be made of materials such as silicon, germanium, a compound semiconductor including silicon-germanium, silicon carbide, gallium arsenide, gallium phosphide, indium phosphide, indium arsenide, and/or indium antimonide; alloy semiconductors such as SiGe, GaAsP, AlInAs, AlGaAs, GaInAs, GaInP, and/or GaInAsP; or combinations thereof. Other substrates, such as multi-layered or gradient substrates, may also be used. The semiconductor substrate 110 may be doped or undoped. Devices such as transistors, capacitors, resistors, diodes, and the like may be formed in and/or on the active surface of the semiconductor substrate 110.

The interconnection structure 120 is located on the semiconductor substrate 110 and includes multiple conductive layers. For example, the interconnection structure 120 may include conductive features 126, a seal ring 122, and others. The interconnection structure 120 also includes an insulating structure 128, within which the conductive features 126 and the seal ring 122 are distributed. The insulating structure 128 may be composed of multiple insulating layers, such as silicon oxide, silicon nitride, silicon oxynitride, other insulating materials, or combinations thereof. In some embodiments, the interconnection structure 120 further includes interconnection layers (not shown) that are distributed within the insulating structure 128. These interconnection layers are positioned near the center area of the insulating structure 128 and are electrically connected to the semiconductor substrate 110.

In some embodiments, the conductive features 126 are aluminum pads, but the disclosure is not limited thereto. In other embodiments, the conductive features 126 may include different materials and structures. Furthermore, in some embodiments, additional conductive layers may be interposed between the conductive feature 126 and the semiconductor substrate 110. The seal ring 122 may be disposed adjacent to side surfaces of the first die 100. The seal ring 122 may be configured to protect the interconnection layers (not shown) from contamination and/or physical damage during device processing, such as plasma etching and/or deposition processes. The seal ring 122 may include copper, but other suitable materials for the seal ring 122 are within the scope of the disclosure. The seal ring 122 may include conductive lines and via structures that are connected to each other and may be formed simultaneously with the interconnection layers (not shown) in the center area of the interconnection structure 120. The seal ring 122 may be floating, grounded, or electrically connected to a fixed voltage.

A first bonding layer 130 is disposed on the interconnection structure 120 and includes metal pads 132 and an insulating layer 134. In some embodiments, the metal pads 132 may be made of copper or other suitable materials, and the insulating layer 134 may be composed of silicon oxide or other insulation materials. At least a part of the metal pads 132 are electrically connected to the interconnection structure 120.

A carrier structure 300 is provided. The carrier structure 300 may be any structure containing circuits, such as an interposer structure, a bottom die, or a circuit board. In the present embodiment, the carrier structure 300 is an interposer structure that includes a substrate 310 and an interconnection structure 320 located on the substrate 310. In some embodiments, the substrate 310 may also be referred to as a core substrate.

In some embodiments, the substrate 310 is made of a semiconductor material, such as silicon, germanium, a compound semiconductor including silicon-germanium, silicon carbide, gallium arsenide, gallium phosphide, indium phosphide, indium arsenide, and/or indium antimonide; alloy semiconductors such as SiGe, GaAsP, AlInAs, AlGaAs, GaInAs, GaInP, and/or GaInAsP; or combinations thereof. Multiple through-substrate vias (TSVs) 315 are located in the substrate 310 and are electrically connected to the interconnection structure 320.

In this embodiment, the TSVs 315 have already passed through the substrate 310 at this stage, but the disclosure is not limited thereto. In other embodiments, the substrate 310 may be thinned in later processing steps, and the TSVs 315 may pass through the substrate 310 after it has been thinned. The TSVs 315 may be made of conductive materials such as copper (Cu), titanium (Ti), tantalum (Ta), or other suitable metallic materials.

The interconnection structure 320 includes multiple interconnection layers and an insulating structure that surrounds these interconnection layers. The interconnection layers of different levels are electrically connected through vias. The interconnection structure 320 is electrically connected to the TSVs 315.

A second bonding layer 330 is formed on the interconnection structure 320 and includes metal pads 332 and an insulating layer 334. In some embodiments, the metal pads 332 may be made of copper or other suitable materials, and the insulating layer 334 may be composed of silicon oxide or other insulating materials. At least a portion of the metal pads 332 are electrically connected to the interconnection structure 320. In this embodiment, the interconnection structure 320 electrically connects the metal pads 332 to the TSVs 315, but the disclosure is not limited thereto.

The first bonding layer 130 of the first die 100 is bonded to the second bonding layer 330 of the carrier structure 300 through hybrid bonding. For example, the metal pads 132 and the metal pads 332 are connected through metal-to-metal bonding, while the insulating layer 334 and the insulating layer 134 are connected through oxide-to-oxide bonding. In some embodiments, the hybrid bonding between the first die 100 and the carrier structure 300 may be a die-to-wafer or die-to-die hybrid bonding.

Referring to FIGS. 1B and 2B, second dies 200 are attached to the carrier structure 300. In some embodiments, the second dies 200 are positioned along the cutting line for a subsequent singulation process. For example, in later processing, a singulation process is used to cut the structure into multiple separate package components, with the second dies 200 placed at the locations where the cutting will occur, ensuring that the second dies 200 are positioned at the edges of the package components.

In this embodiment, the second dies 200 are not used for signal transmission and therefore do not need to be electrically connected to the carrier structure 300. In some embodiments, the second dies 200 are bonded to the carrier structure 300 using die attach films 210, but this disclosure is not limited thereto. In other embodiments, the second dies 200 are attached to the carrier structure 300 using other bonding techniques, and the second dies 200 may be electrically connected to the carrier structure 300. In some embodiments, the coefficient of thermal expansion (CTE) of the die attach films 210 is higher than that of the second dies 200. The difference in CTE may lead to stress during the manufacturing process, potentially causing cracks, particularly at the corner regions of the package component.

In this embodiment, the entire bottom surface of the die attach films 210 contacts the insulating layer 334, but this disclosure is not limited thereto. In other embodiments, the bottom surface of the die attach film 210 is in contact with the dummy pads (not shown) of the second bonding layer 330.

The second dies 200 may include materials that are the same as or different from the semiconductor substrate 110. In some embodiments, the second dies 200 include semiconductor materials such as silicon, germanium, compound semiconductors including silicon-germanium, silicon carbide, gallium arsenide, gallium phosphide, indium phosphide, indium arsenide, and/or indium antimonide; alloy semiconductors such as SiGe, GaAsP, AlInAs, AlGaAs, GaInAs, GaInP, and/or GaInAsP; or combinations thereof.

Referring to FIGS. 1C and 2C, an encapsulation layer 400, which may be a molding compound, is formed between the first die 100 and the second die 200. The molding compound may include a resin and a filler. The encapsulation layer 400 surrounds the first dies 100 and the second dies 200, and corners and sidewalls of the first die 100 are covered by the encapsulation layer 400.

In some embodiments, the CTE of the encapsulation layer 400 is higher than that of the first die 100. This CTE mismatch may result in thermal stress, reducing the production yield of the package components. In this embodiment, by placing second dies 200 at the edge positions of the package components, thermal stress may be mitigated. The CTE of the second dies 200 is lower than that of the encapsulation layer 400 and closer to that of the first die 100. In this embodiment, the second dies 200 may also be referred to as dummy dies or stress relief structures, which are used for reducing thermal stress in the package components. Depending on the positional requirements, second dies 200 of varying sizes may be used. For example, larger second dies 200 are used at the corners of the package components.

In some embodiments, the first bonding layer 130 of the first die 100 is recessed, allowing an extending portion 402 of the encapsulation layer 400 to fill the space between the first die 100 and the carrier structure 300 and to be vertically positioned between them. For example, during the manufacturing of the first die 100, shallow plasma dicing (SPD) or other suitable processes may be employed to create the recess in the first bonding layer 130. By filling the extending portion 402 of the encapsulation layer 400 between the first die 100 and the carrier structure 300, the likelihood of cracks caused by the expansion of the encapsulation layer 400 may be reduced.

Referring to FIG. 1D, a first grinding process is performed on the encapsulation layer 400. In this embodiment, the top surfaces of the first die 100 and the second die 200 are not exposed during the grinding process. However, in other embodiments, the top surfaces of the first die 100 and the second die 200 may be exposed through the first grinding process.

Referring to FIG. 1E, a temporary carrier 500 is provided over the encapsulation layer 400. In some embodiments, the temporary carrier 500 is a glass carrier, polymer carrier, or any suitable carrier for the semiconductor manufacturing. The carrier 500 is provided with a debonding layer 502 coated thereon. In some embodiments, a debonding layer 502 may be made of any material suitable for bonding and debonding the temporary carrier 500 from the encapsulation layer 400. In some embodiments, the debonding layer 502 includes an epoxy-based thermal-release material, which loses its adhesive property when being heated, such as a light-to-heat-conversion (LTHC) release coating film. In alternative embodiments, the debonding layer 502 includes an ultra-violet (UV) glue, which loses its adhesive property when exposed to UV lights. In some embodiments, the debonding layer 502 may be dispensed as a liquid and cured, or may be a laminate film, or the like.

Referring to FIG. 1F, the entire structure is flipped, and an insulating layer 340 is formed on the backside of the substrate 310, opposite to the first die 100 and the second die 200. In some embodiments, a backside redistribution (RDL) structure is formed on the backside of the substrate 310 prior to forming the insulating layer 340; however, the present disclosure is not limited thereto.

Conductive vias 342 are formed in the insulating layer 340 and are electrically connected to the TSVs 315. Conductive features 344 are disposed on the conductive vias 342. In some embodiments, the conductive vias 342 and the conductive features 344 are formed simultaneously. The conductive features 344 may include conductive pillars, under-bump metallization (UBM), or other conductive structures.

Conductive terminals 600 are formed on the conductive features 344 and are electrically connected to the TSVs 315. The conductive terminals 600 may include micro-bumps, metal pillars, ENEPIG bumps, C4 bumps, ball grid array (BGA) bumps, or other suitable connection structures.

Referring to FIG. 1G, a protective tape 610 is adhered to the conductive terminals 600, and the entire structure is flipped. The temporary carrier 500 is then removed through a debonding process. Subsequently, a second grinding process is performed on the encapsulation layer 400. In some embodiments, the second grinding process is carried out until the top surfaces of the first die 100 and the second die 200 are exposed. In other embodiments, other fixing structures may be used to replace the protective tape 610.

Referring to FIG. 1H, a protective tape 620 is adhered to the first die 100, the second die 200, and the encapsulation layer 400, and the structure is flipped again. In other embodiments, other fixing structures may be used to replace the protective tape 620. The protective tape 610 is removed.

Referring to FIG. 1i and 2d, a Dicing Process Is Performed Along the Cutting Line,

which extends through and across the second dies 200. The dicing process is initiated from the bottom surface 300b of the carrier structure 300 and follows the designated cutting line.

The dicing process forms a trench LS1 that extends from the bottom surface 300b of the carrier structure 300 to the second dies 200. The trench LS1 defines the boundaries of the package components. In some embodiments, the trench LS1 formed by the dicing process has a width less than that of the second dies 200. The trench LS1 penetrates through the carrier structure 300 and into the second dies 200. In certain embodiments, the trench LS1 extends through the second bonding layer 330 and the die attach films 210. In this embodiment, the trench LS1 does not extend entirely through the second dies 200.

In some embodiments, the dicing process may be a dry etching, a wet etching process, or a combination thereof. For instance, a laser process may be employed to create the trench LS1.

FIGS. 1J and 1K are schematic cross-sectional views taken along lines A-A′ and B-B′ in FIG. 2E, respectively, where the position shown in FIG. 1J is closer to the corner of the package component compared to the position in FIG. 1K. Referring to FIGS. 1J, 1K, and 2E, a grooving process is performed to remove at least some corners of at least some first die 100. In this embodiment, some corners of the first die 100 near the corners of the package component are removed, while the other corners of the first die 100, located farther from the corners of the package component, remain intact. In this embodiment, from the top view (referring to FIG. 2E), the top two corners of the top first die 100 and the bottom two corners of the bottom first die 100 in one package component are removed during the grooving process. In other embodiments, all four corners of each first die 100 may be removed during the grooving process. In other words, the present disclosure does not limit the grooves LS2 to being located only at the four corners of the package component. Instead, each corner of the first die 100 may include a groove LS2.

The removed corners include portions of both the first bonding layer 130 and the second bonding layer 330. For example, a groove LS2 is formed at the corner of the first die 100 by the grooving process. The groove LS2 extends from the bottom surface 300b of the carrier structure 300 to the first die 100, passing through both the first bonding layer 130 and the second bonding layer 330. In this embodiment, portions of the insulating layer 340, the substrate 310, the interconnection structure 320, the second bonding layer 330, the first bonding layer 130, the interconnection structure 120, the encapsulation layer 400, the die attach film 210, and the second die 200 are removed by the grooving process. The groove LS2 extends into the interconnection structure 120. In some embodiments, the grooving process may also remove a portion of the semiconductor substrate 110, causing the groove LS2 to further extend into the semiconductor substrate 110.

In some embodiments, the extending portion 402 of the encapsulation layer 400 may also be partially removed during the grooving process. In this embodiment, the sidewall SW of the groove LS2 may or may not include the remaining portion of the extending portion 402. In other words, the extending portion 402 of the encapsulation layer 400 may be located on the sidewall SW of the groove LS2. In this embodiment, the sidewall SW of the groove LS2 includes a portion of the sidewall 300s of the carrier structure 300, a portion of the sidewall of the extending portion 402, a portion of the sidewall 100s of the first die 100. The bottom surface BS of the groove LS2 includes a portion of a bottom surface 100b of the first die 100, a portion of a bottom surface 400b of the encapsulation layer 400, and a portion of a bottom surface 200b of the second die 200. In this embodiment, the extending portion 402 is located between the portion of the sidewall 300s of the carrier structure 300 and the portion of the sidewall 100s of the first die 100, but the disclosure is not limited thereto.

In some embodiments, the grooving process may be a dry etching, a wet etching process, or a combination thereof. For instance, a laser process may be employed to create the groove LS2.

In this embodiment, the groove LS2 and the trench LS1 have the same depth, but this is not limiting. In other embodiments, the groove LS2 and the trench LS1 may have different depths. In this embodiment, the groove LS2 is connected to the trench LS1, but the disclosure is not limited thereto. In other embodiments, the groove LS2 is separated from the trench LS1.

In this embodiment, the trench LS1 is formed first, followed by the groove LS2. However, this sequence is not limiting. In other embodiments, the groove LS2 may be formed first, followed by the trench LS1, or the trench LS1 and the groove LS2 may be formed simultaneously. For example, when the groove LS2 substantially surrounds the entire edge of the package component, the trench LS1 and the groove LS2 may effectively be indistinguishable and should be regarded as the same structure. In such case, the dicing process used to form the trench LS1 may be omitted.

In this embodiment, the grooving process removes areas that are prone to bonding failures, thereby preventing the occurrence of cracks and, consequently, avoiding delamination issues caused by crack propagation.

FIGS. 1L and 1M are schematic cross-sectional views taken along lines A-A′ and B-B′ in FIG. 2F, respectively, where the position shown in FIG. 1L is closer to the corner of the package component compared to the position in FIG. 1M. Referring to FIGS. 1L, 1M, and 2F, a singulation process is performed along the cutting line overlapping the second dies 200. In some embodiments, the cutting line is separated from the first dies 100. The singulation process is performed along the trench LS1 and the second dies 200. After the singulation process, multiple separated package components 10 may be obtained. The second dies 200 are positioned along the outermost sidewall 10s of each package component 10. In some embodiments, the singulation process may include a sawing process, a laser ablation process, an etching process, or combinations thereof. In some embodiments, the protective tape 620 is removed either before or after the singulation process.

In this embodiment, each package component 10 has grooves LS2 at its corners. Removing the corners that are prone to crack may improve the yield of the package components 10.

In this embodiment, the grooves LS2 and the trenches LS1 form stepped structures SS within the package component 10. The stepped structure SS includes portions of the sidewall 300s of the carrier structure 300, the sidewall 402s of the extending portion 402, the sidewall 100s of the first die 100, the bottom surface 100b of the first die 100, the bottom surface 400b of the encapsulation layer 400, the bottom surface 200b of the second die 200, and the sidewall 200s of the second die 200, arranged in sequence. In this embodiment, the outermost sidewall 10s of the package component 10 includes the sidewall 200s of the second dies 200. The groove LS2 extends from the first die 100 to the outermost sidewall 10s of the package component 10, and the trench LS1 is located at the outermost sidewall 10s of the package component 10. The encapsulation layer 400 is closer to the outermost sidewall 10s of the package component 10 than the first die 100.

In some embodiments, the package component 10 includes a System on a Chip (SoC).

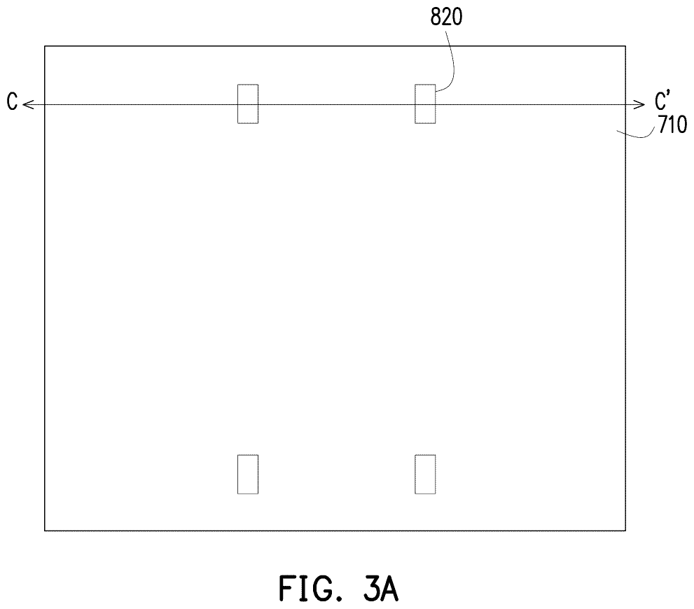

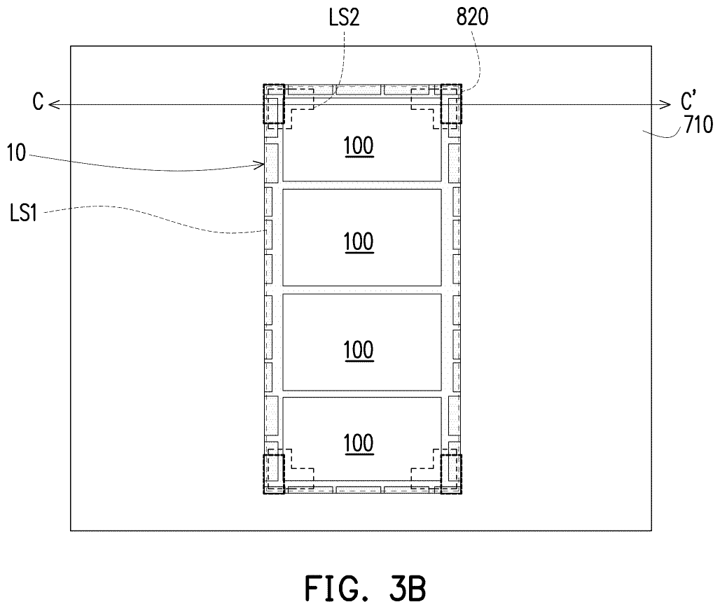

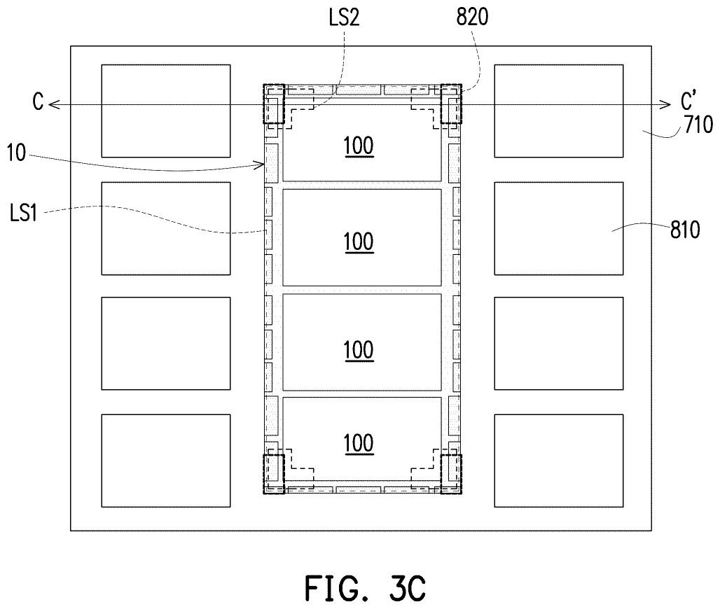

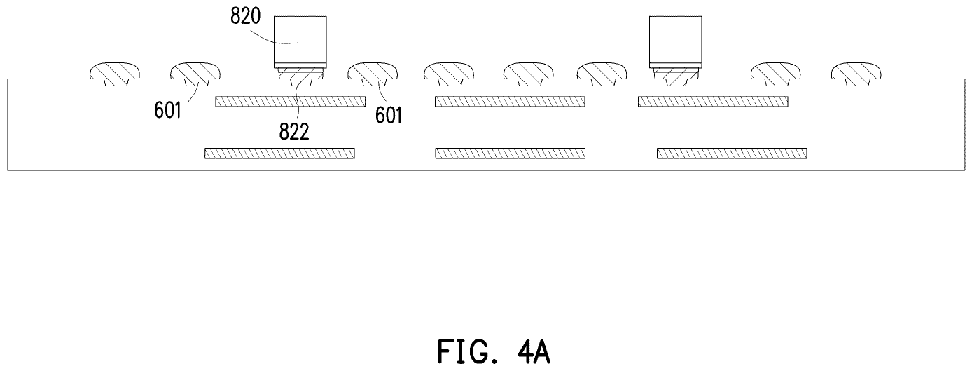

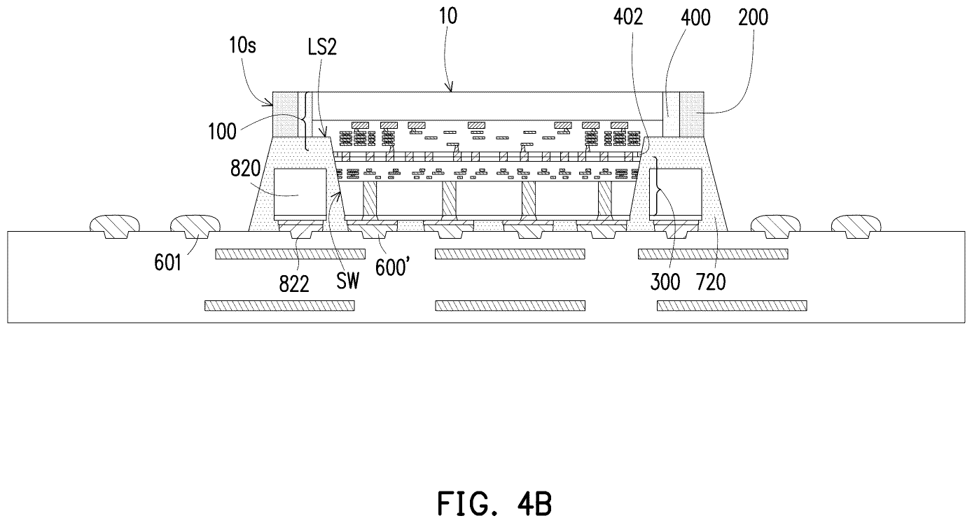

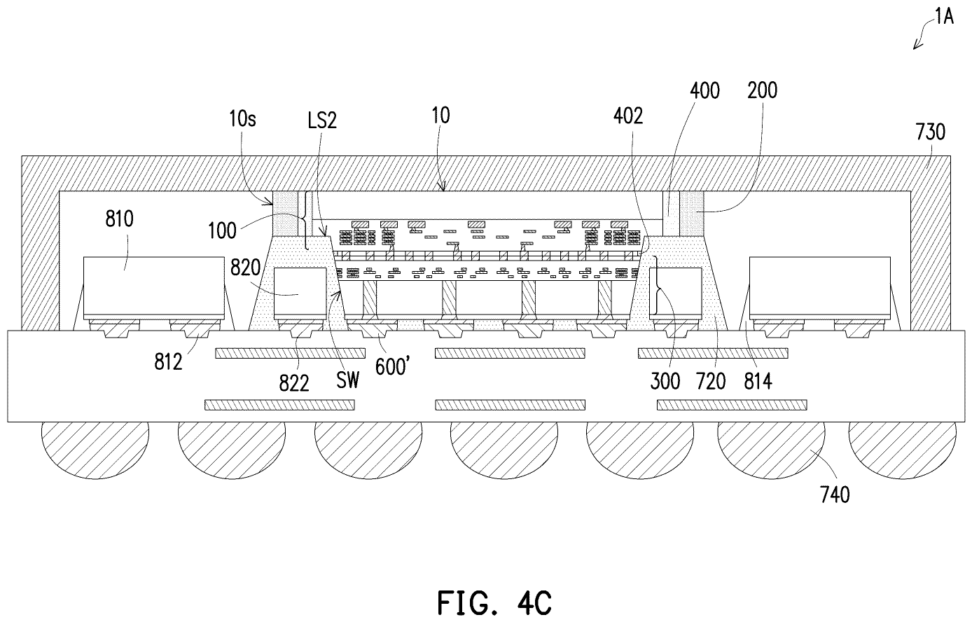

FIGS. 3A to 3C are schematical top views illustrating various stages of a method for bonding a package component 10 to a package substrate 710 according to some embodiments of the present disclosure. FIGS. 4A to 4C are schematical cross-sectional views taken along lines C-C′ in FIG. 3A to 3C, respectively. Referring to FIGS. 3A and 4A, a package substrate 710 is provided. First auxiliary structures 820 are bonded to the package substrate 710. For example, the first auxiliary structures 820 may be bonded to the package substrate 710 through at least one of a die attach film, a solder ball, or a conductive bump. In this embodiment, the connection structure 822 between the first auxiliary structures 820 and the package substrate 710 includes solder balls. In some embodiments, the first auxiliary structures 820 are dummy dies, integrated passive devices (IPDs), or the like.

In some embodiments, the surface of the package substrate 710 optionally includes multiple conductive connection structures 601. These conductive connection structures 601 are used to bond the package substrate 710 to other structures that will subsequently be mounted on it. In certain embodiments, the conductive connection structures 601 may include solder, conductive bumps, or the like. In some embodiments, the conductive connection structures 601 may be omitted.

Referring to FIGS. 3B and 4B, the package component 10 is bonded to the package substrate 710. For example, a flux layer is applied to the package component 10 and/or the package substrate 710. The package component 10 is then bonded to the package substrate 710 through a soldering process. The conductive terminals 600 on the package component 10 combine with the conductive connection structures 601 on the package substrate 710 to form conductive joints 600′. The excess flux layer is subsequently removed.

In this embodiment, the first auxiliary structures 820 overlap with the grooves LS2 located on the bottom side of the package component 10, which faces the package substrate 710. Each first auxiliary structure 820 is vertically positioned between the second die 200 and the package substrate 710, between the encapsulation layer 400 and the package substrate 710, and between the first die 100 and the package substrate 710.

An underfill layer 720 (not shown in FIG. 3B) is formed between the package component 10 and the package substrate 710. The underfill layer 720 is vertically disposed between the package substrate 710 and the package component 10 and contacts the sidewall SW of the groove LS2. In this embodiment, the underfill layer 720 also contacts the sidewall of the trench LS1 (referring to FIGS. 1M and 2F). In some embodiments, the underfill layer 720 contacts the carrier structure 300, the encapsulation layer 400, the first die 100, and the second die 200 through the groove LS2. In this embodiment, the underfill layer 720 covers the portion of the first die 100 exposed by the groove LS2, providing protection for the first die 100.

In addition, the underfill layer 720 is vertically disposed between the package component 10 and the first auxiliary structures 820. The underfill layer 720 is in contact with a bottom surface of the second die 200 and a top surface of the first auxiliary structure 820. The underfill layer 720 is laterally located between the sidewall SW of the groove LS2 and a sidewall of the first auxiliary structure 820.

In this embodiment, the first auxiliary structures 820 are completely covered by the package component 10 and do not extend beyond the outermost sidewalls 10s of the package component 10; however, this disclosure is not limited thereto. In other embodiments, the first auxiliary structures 820 may extend beyond the outermost sidewalls 10s of the package component 10. In this embodiment, the underfill layer 720 covers the entire top surfaces and the entire sidewalls of the first auxiliary structures 820; however, this disclosure is not limited thereto. In other embodiments, portions of the first auxiliary structures 820 may be exposed from the underfill layer 720.

In this embodiment, the CTE of the first auxiliary structures 820 is less than the CTE of the underfill layer 720. For example, the CTE of the first auxiliary structures 820 is close to the CTE of the first die 100 and/or the CTE of the second die 200. By positioning the low-CTE first auxiliary structures 820 beneath the grooves LS2, issues caused by CTE mismatch may be mitigated.

Referring to FIGS. 3C and 4C, additional devices may be mounted on the package substrate 710. For example, the first dies 100 in the package component 10 may be logic dies, and additional memory dies 810 may be attached to the package substrate 710. In some embodiments, the memory dies 810 may be bonded to the package substrate 710 through at least one of a die attach film, a solder ball, or a conductive bump. In this embodiment, the connection structure 812 between the memory dies 810 and the package substrate 710 is formed by soldering the conductive connection structures 601 to the solder balls (not individually shown) on the memory dies 810. In certain embodiments, passive devices (e.g., capacitors, resistors, inductors, varactors, and/or similar components) are also mounted on the package substrate 710, for instance, using surface mount technology (SMT) connections.

An underfill layer 814 is formed between the memory dies 810 and the package substrate 710, surrounding the connection structure 812.

A heat dissipation structure 730 is disposed on the package substrate 710, covering the package component 10. The heat dissipation structure 730 may include a ring, a lid, heat sink fins, a combination thereof, or other suitable structures. In some embodiments, the heat dissipation structure 730 is bonded to the package substrate 710 using an adhesive layer (not shown). In certain embodiments, a thermal interface material (not shown) is interposed between the heat dissipation structure 730 and the package component 10. In this embodiment, the heat dissipation structure 730 covers the package component 10, the first auxiliary structures 820, and the memory dies 810; however, this disclosure is not limited thereto. In other embodiments, the memory dies 810 may be positioned outside the heat dissipation structure 730.

Subsequently, connection terminals 740 are formed on the side of the package substrate 710 opposite the package component 10. The connection terminals 740 may include solder balls or other suitable connection structures.

In this embodiment, the package 1A includes the package substrate 710, the package component 10, the memory dies 810, the first auxiliary structure 820, the underfill layers 720 and 814, the heat dissipation structure 730, and the connection terminals 740. The inclusion of the first auxiliary structure 820 may improve the yield of the package 1A.

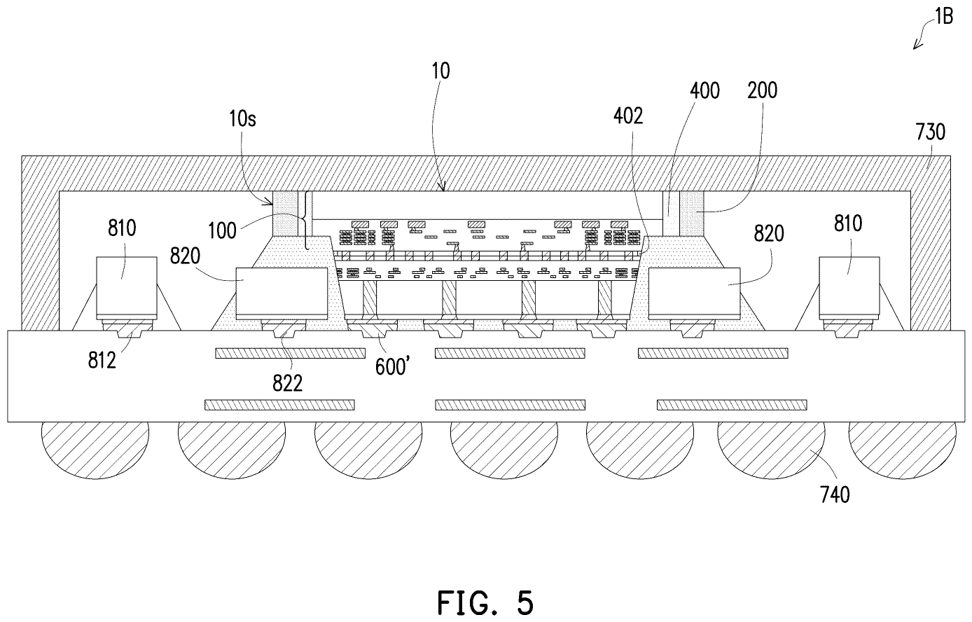

FIG. 5 is a schematic cross-sectional view illustrating a package 1B according to some embodiments of the present disclosure. The package 1B in FIG. 5 is similar to the package 1A in FIG. 4B, with the difference being that, in the package 1B in FIG. 5, the first auxiliary structures 820 may extend beyond the outermost sidewalls 10s of the package component 10, and portions of the first auxiliary structures 820 may be exposed from the underfill layer 720.

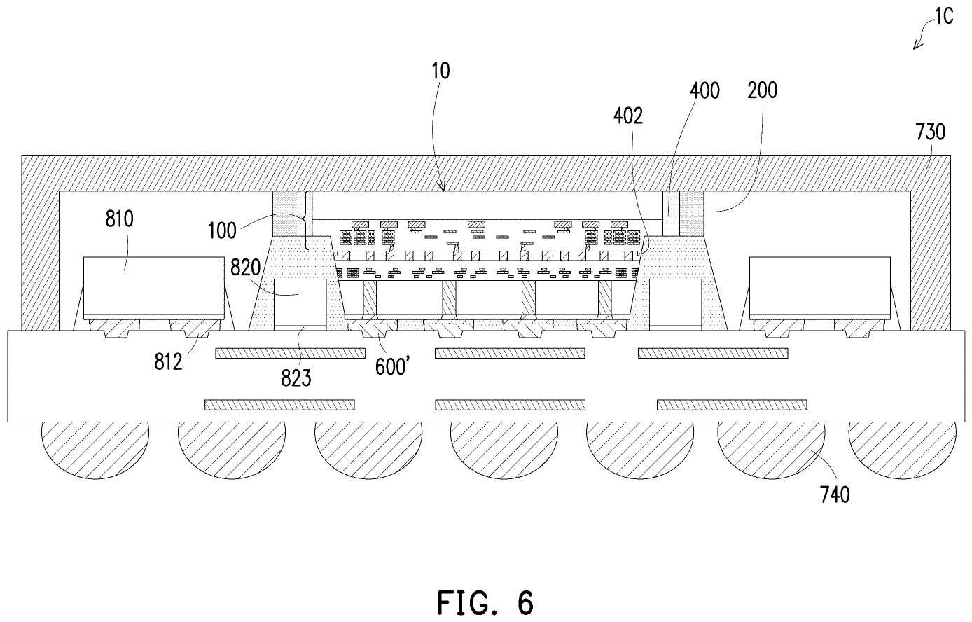

FIG. 6 is a schematic cross-sectional view illustrating a package 1C according to some embodiments of the present disclosure. The package 1C in FIG. 6 is similar to the package 1A in FIG. 4B, with the difference being that, in the package 1C in FIG. 6, the first auxiliary structures 820 are bonded to the package substrate 710 through die attach films 823.

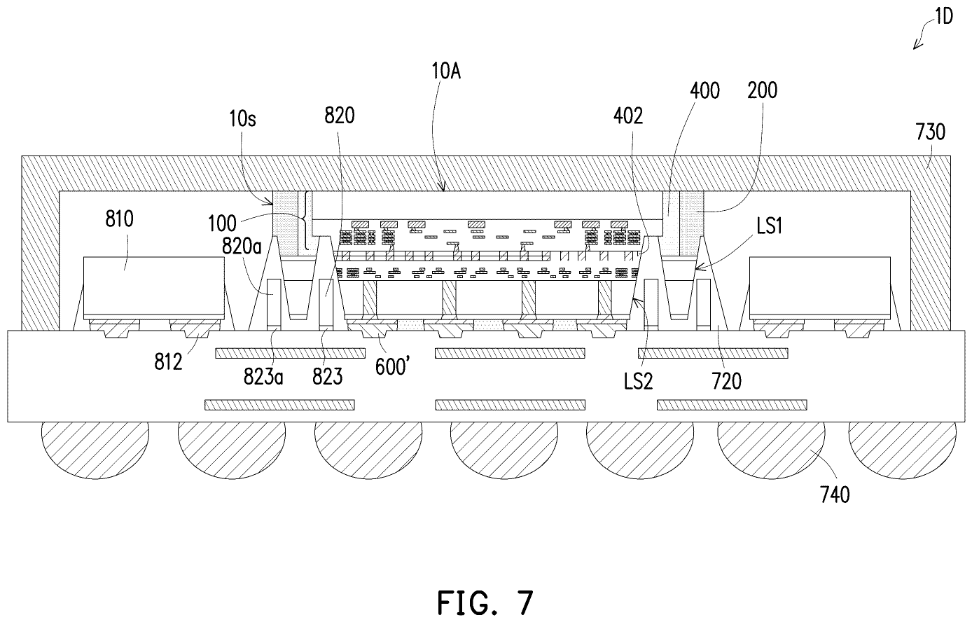

FIG. 7 is a schematic cross-sectional view illustrating a package 1D according to some embodiments of the present disclosure. The package 1D in FIG. 7 is similar to the package 1A in FIG. 4B, with the difference being that, in the package 1D in FIG. 7, the groove LS2 is separated from the trench LS1. For example, the trench LS1 extends along the outermost sidewall 10s of the package component 10A, while the groove LS2 is positioned apart from the outermost sidewall 10s of the package component 10A.

In this embodiment, the groove LS2 does not extend into the second die 200, allowing part of the second die 200 to be laterally positioned between the groove LS2 and the trench LS1.

In this embodiment, at least part of the corners of the first die 100 are removed through the grooving process, thereby preventing crack propagation at the corners and avoiding delamination issues. In some embodiments, four grooves LS2 are positioned near the four corners of the package component 10A. However, this disclosure is not limited thereto. In other embodiments, each corner of the first die 100 may include a groove LS2, or a single groove LS2 may surround multiple first dies 100 along the peripheral region of the package component 10A.

In this embodiment, the first auxiliary structures 820 are bonded to the package substrate 710 through die attach films 823, and second auxiliary structures 820a are bonded to the package substrate 710 through die attach films 823a. The first auxiliary structures 820 are overlapping with the grooves LS2, and the second auxiliary structures 820a are overlapping with the trench LS1. A portion of the package component 10A is laterally located between the first auxiliary structures 820 and the second auxiliary structures 820a.

In some embodiments, the first auxiliary structures 820 and the second auxiliary structures 820a are dummy dies, integrated passive devices (IPDs), or the like.

In this embodiment, the CTE of the first auxiliary structures 820 and the CTE of the second auxiliary structures 820a are both less than the CTE of the underfill layer 720. For example, the CTE of the first auxiliary structures 820 and the CTE of the second auxiliary structures 820 are close to the CTE of the first die 100 and/or the CTE of the second die 200. By positioning the first auxiliary structures 820 and the second auxiliary structures 820a, issues caused by CTE mismatch may be mitigated.

In accordance with some embodiments of the present disclosure, package includes a package substrate, a package component, a first auxiliary structure, and an underfill layer. The package component is bonded to the package substrate. The package component has a groove at a bottom side facing the package substrate. The first auxiliary structure is bonded to the package substrate and overlapping with the groove. The underfill layer is vertically disposed between the package component and the package substrate and between the package component and the first auxiliary structure.

In accordance with some embodiments of the present disclosure, a package includes a package substrate, a package component, a first auxiliary structure, and an underfill layer. The package component includes an interposer structure, a first die, a second die, and an encapsulation layer. The first die and the second die are bonded to the interposer structure. The encapsulation layer is located between the first die and the second die and surrounding the first die. The package component has a groove located at a corner of the first die. The first auxiliary structure is bonded to the package substrate. The first auxiliary structure is overlapping with the groove and vertically disposed between the first die and the package substrate. The underfill layer is vertically disposed between the package component and the package substrate. A coefficient of thermal expansion of the first auxiliary structure is less than a coefficient of thermal expansion of the underfill layer.

In accordance with some embodiments of the present disclosure, a fabrication method of a package includes the following steps. A first die and a second die are bonded to a carrier structure. An encapsulation layer is formed between the first die and the second die. A grooving process is performed to remove a corner of the first die, wherein a groove is formed at the corner of the first die. A singulation process is performed along a cutting line overlapping the second die to obtain a package component. A first auxiliary structure is bonded to a package substrate. The carrier structure is bonded to the package substrate, wherein the groove of the package component is overlapping with the first auxiliary structure. An underfill layer is formed between the package component and the package substrate.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package, comprising:
a package substrate;
a package component, bonded to the package substrate, wherein the package component has a groove at a bottom side facing the package substrate;
a first auxiliary structure, bonded to the package substrate and overlapping with the groove; and
an underfill layer, vertically disposed between the package component and the package substrate and between the package component and the first auxiliary structure.

2. The package of claim 1, wherein the package component comprises:
a carrier structure;
a first die, wherein a first bonding layer of the first die is bonded to a second bonding layer of the carrier structure, wherein the groove extends from a bottom surface of the carrier structure to the first die, passing through both the first bonding layer and the second bonding layer;
a second die, located at an outermost sidewall of the package component; and
an encapsulation layer, located between the first die and the second die and surrounding the first die, wherein the encapsulation layer is closer to the outermost sidewall of the package component than the first die.

3. The package of claim 2, wherein the first auxiliary structure is vertically disposed between the second die and the package substrate, and the underfill layer is in contact with a bottom surface of the second die and a top surface of the first auxiliary structure.

4. The package of claim 2, wherein an extending portion of the encapsulation layer is vertically located between the first die and the carrier structure.

5. The package of claim 1, wherein the underfill layer covers a top surface of the first auxiliary structure and a sidewall of the first auxiliary structure.

6. The package of claim 1, wherein the groove is separated from an outermost sidewall of the package component, and a trench is located at the outermost sidewall of the package component, wherein a second auxiliary structure is overlapping with the trench, and a portion of the package component is laterally located between the first auxiliary structure and the second auxiliary structure.

7. The package of claim 6, wherein the package component comprises:
a carrier structure;
a first die, wherein the groove is located at a corner of the first die;
a second die, located at the outermost sidewall of the package component, and the trench is located at the second die.

8. The package of claim 1, wherein a coefficient of thermal expansion of the first auxiliary structure is less than a coefficient of thermal expansion of the underfill layer.

9. The package of claim 1, wherein the first auxiliary structure is a dummy die or an integrated passive device.

10. A package, comprising:
a package substrate;
a package component, comprising;
an interposer structure;
a first die and a second die, bonded to the interposer structure; and
an encapsulation layer, located between the first die and the second die and surrounding the first die, wherein the package component has a groove located at a corner of the first die; and
a first auxiliary structure, bonded to the package substrate, wherein the first auxiliary structure is overlapping with the groove and vertically disposed between the first die and the package substrate; and
an underfill layer, vertically disposed between the package component and the package substrate, wherein a coefficient of thermal expansion of the first auxiliary structure is less than a coefficient of thermal expansion of the underfill layer.

11. The package of claim 10, wherein the first auxiliary structure is a dummy die or an integrated passive device.

12. The package of claim 10, wherein the underfill layer is in contact with a top surface of the first auxiliary structure and a sidewall of the first auxiliary structure.

13. The package of claim 10, wherein the first auxiliary structure is bonded to the package substrate by a die attach film, a solder ball, or a conductive bump.

14. The package of claim 10, wherein the underfill layer is laterally located between a sidewall of the groove and a sidewall of the first auxiliary structure.

15. A fabrication method of a package, comprising:
bonding a first die and a second die to a carrier structure;
forming an encapsulation layer between the first die and the second die;
performing a grooving process to remove a corner of the first die, wherein a groove is formed at the corner of the first die; and
performing a singulation process along a cutting line overlapping the second die to obtain a package component;
bonding a first auxiliary structure to a package substrate;
bonding the package component to the package substrate, wherein the groove of the package component is overlapping with the first auxiliary structure; and
forming an underfill layer between the package component and the package substrate.

16. The fabrication method of claim 15, further comprising:
performing a dicing process from a bottom surface of the carrier structure along the cutting line before the singulation process, wherein the dicing process forms a trench extending from a bottom surface of the carrier structure to the second die, and the singulation process is performed along the trench.

17. The fabrication method of claim 16, wherein the groove is connected to the trench.

18. The fabrication method of claim 16, wherein the groove is separated from the trench, and a second auxiliary structure is bonded to the package substrate and overlapping with the trench of the package component.

19. The fabrication method of claim 15, wherein a first bonding layer of the first die is bonded to a second bonding layer of the carrier structure through hybrid bonding, while the second die is bonded to the carrier structure through a die attach film.

20. The fabrication method of claim 15, wherein a coefficient of thermal expansion of the first auxiliary structure is less than a coefficient of thermal expansion of the underfill layer.
